(19) United States
(12) Patent Application Publication
(10) Pub. No.: US 2026/0089851 A1
(43) Pub. Date: Mar. 26, 2026

(54) MODULAR DEVICE WITH INTERCHANGEABLE PARTS

(71) Applicant: Amy Knapp, Etna, OH (US)

(72) Inventor: Amy Knapp, Etna, OH (US)

(21) Appl. No.: 19/339,950

(22) Filed: Sep. 25, 2025

Related U.S. Application Data
(60) Provisional application No. 63/699,369, filed on Sep. 26, 2024.

(51) Int. Cl. H05K 5/00; F04D 25/06; F04D 25/08; F21V 23/02; F24C 15/08

(52) U.S. Cl. CPC H05K 5/0086; F04D 25/06; F04D 25/08; F21V 23/02; F24C 15/08

(57) ABSTRACT

A device is described that is modular and involves interchangeable parts. The device may include a base module electrically linked to an interchangeable attachment module. In one example of the device of the present invention, the base module includes a port for receiving the attachment module and transmitting power directly to the attachment module. The port may additionally or alternatively be capable of receiving an intermediate module and transmitting power to the intermediate module. In this particular example, the intermediate module may receive an attachment module and transmit power to the attachment module. The attachment module may involve electronic features, such as, for example, lights, fans, sound emitting features, scent emitting features, or a combination of these.

### CROSS-REFERENCE TO RELATED APPLICATIONS

This non-provisional patent application is based on and claims priority to U.S. Provisional Ser. No. 63/699,369 , filed Sep. 26, 2024, the disclosure of which is hereby incorporated by reference as if fully recited herein.

### TECHNICAL FIELD

The present invention relates generally to a modular device with interchangeable parts, and more particularly to a modular device with a base module capable of being in electronic communication with an interchangeable attachment module. In one example embodiment, the base module comprises a port for receiving a portable and interchangeable attachment module, and for transmitting power directly to the attachment module. Additionally, or alternatively, the base module port may be configured to receive an intermediate module, and transmit power to the intermediate module. In the aforementioned example embodiment, the intermediate module is configured to receive an attachment module and transmit power to the attachment module. The attachment module may comprise any number of different electronic features, such as, for example, lights, fans, sound emitting devices, scent emitting devices, some combination thereof, or the like. Alternatively, or additionally, the attachment module may comprise non-electronic features.

### BACKGROUND AND SUMMARY OF THE INVENTION

Household electronic devices such as, for example, fans, lights and lanterns, sound emitting devices, and scent emitting devices are well known. Such devices may be portable, and batteries (e.g., rechargeable batteries) may be used to power such devices. Such devices may also be used outdoors. However, the options for arranging such devices in a way most beneficial to a user are limited by the lack of interchangeability of device components. Typically, the user must either hold the device, position the device on the ground, or find an object (e.g., a table) providing an elevated flat surface to position the device on. This may be inconvenient to the user. As a specific, non-limiting example, when a user is sitting in a chair and wants to have a fan blow air on the user's face, the user must either hold the fan proximate to one's face or find a support structure (e.g., a table or other flat, elevated surface) to position the fan on that will hold the fan high enough up to blow air on the user's face. An adequate support structure is often not available.

Where an adequate support structure is available, the support structure may be inconsistent with the user's preferred aesthetic for the device. Furthermore, the support structure generally lacks any ability to transmit power to the device. Where the device is not battery powered, the user is limited to using the device near a wall outlet. For example, although known pedestal fans may not require a separate support structure, they typically must be employed near a wall outlet. Another disadvantage of known pedestal fans and similar known devices is that the operative unit (e.g., the fan itself) lacks the ability to be detached from the pedestal shaft for use as a standalone device. This limits the portability of the device.

In view of this, it is beneficial to have an exemplary modular device with interchangeable parts, including a base module having a power supply port and an interchangeable attachment module, as described in more detail below.

According to the present invention in one aspect, an exemplary modular device with interchangeable parts comprises a base comprising a base housing, power module and a first port, wherein the first port is in electronic communication with the power module. The device may include an attachment, comprising an attachment housing and a first connector. The first port may be configured to transmit power through the first connector into the attachment. The first connector may be configured for mechanical connection to the first port to cause the attachment to be removably secured above the base. The power module may comprise one or more batteries.

The device may further comprise an intermediate attachment having an intermediate attachment housing, a second connector and a second port. The second connector may be configured for mechanical connection to the first port to removably secure the intermediate attachment to the base. The first connector may be configured for mechanical connection to the second port to removably secure the attachment to the intermediate attachment, and to establish an electrical path from the power module through the intermediate attachment to the attachment. The attachment may comprise an electronic device capable of being powered by the power module of the base. The attachment may comprise an electronic device capable of being powered by the power module of the base, and the intermediate attachment may be configured to transmit power from the power module to the electronic device. The intermediate attachment housing may define an elongated pedestal shaft.

According to the present invention in another aspect, an exemplary modular device with interchangeable parts comprises a base, including a first housing, a power module disposed within the first housing, and a first interface comprising a port having a first mechanical coupling and a first electrical terminal. The first interface may be located at a top face of the base. A first attachment, including a second housing, a second interface comprising a second mechanical coupling and a second electrical terminal, may be provided. The second interface may be configured, when engaged with the first interface, to mechanically secure the first attachment to the base, and to establish an electrical path from the power module to the first attachment.

The first attachment may be configured to be secured above the base. The device may further comprise a second attachment configured to be removably secured between the base and first attachment, and to establish an electric path from the first interface to the second interface. The second attachment may be configured to be removably secured above the base and below the first attachment. The first attachment may further comprise an electronic device configured to receive power from the second interface. The electronic device may include a fan, light, hot plate, some combination thereof, or the like.

According to the present invention in another aspect, an exemplary modular device with interchangeable parts comprises a base, including a first housing, a power module disposed within the first housing, and a first interface comprising a port having a first mechanical coupling and a first electrical terminal. The first interface may be located at a top face of the base. A first attachment, including a second housing, a second interface comprising a second mechanical coupling and a second electrical terminal, and a third interface comprising a third mechanical coupling and a third electrical terminal, may be provided. The second interface may be configured, when engaged with the first interface, to mechanically secure the first attachment to the base, and to establish an electrical path from the power module to the third electrical terminal. A second attachment, including a third housing, a fourth interface comprising a fourth mechanical coupling and a fourth electrical terminal, may be provided. The fourth interface may be configured, when engaged with the third interface, to mechanically secure the second attachment to the first attachment, and establish an electrical path from the first attachment to the second attachment.

The second interface may be located at a bottom surface of the first attachment. The third interface may be located at a top surface of the first attachment. The fourth interface may be located at a bottom surface of the second attachment, and the first attachment may be configured to be removably secured above the base and below the second attachment. The second attachment may include an electronic device configured to receive power from the fourth interface. The electronic device of the second attachment may include a fan. The electronic device of the second attachment may alternatively or additionally include a light.

Exemplary embodiments of the present invention may be highly portable, and offer any number of different interchangeability opportunities. Exemplary embodiments may be advantageous for, by way of example and not limitation, arranging different operative electronic device units on a power supplying base, supporting and securing an operative electronic device unit at a particular location (e.g., at a particular height, angle, and distance with respect to the user) (such by using one of any number of different interchangeable intermediate modules), maintaining a power supply to an electronic device (e.g., by establishing electronic communication between a base unit and attachment unit of the device), achieving a desired aesthetic, saving the user both money and space by allowing for multiple electronic devices to be powered/charged by one base unit, and/or for allowing one electronic device to be powered/charged by multiple base units, some combination thereof, or the like.

### BRIEF DESCRIPTION OF THE DRAWINGS

Novel features and advantages of the present invention, in addition to those expressly mentioned herein, will become apparent to those skilled in the art from a reading of the following detailed description in conjunction with the accompanying drawings. The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 illustrates a perspective view of an exemplary modular device of the present invention, comprising a pedestal base and shaft, and fan attachment;

FIG. 2 illustrates an exploded perspective view of the exemplary modular device of FIG. 1;

FIG. 3 illustrates a left-side, elevational view of the exemplary modular device of FIG. 1;

FIG. 4 illustrates a perspective view of an exemplary pedestal base and shaft, in accordance with a preferred embodiment of the present invention;

FIG. 5 illustrates a perspective view of an exemplary modular device base configured to be connected to an exemplary modular device lantern, in accordance with a preferred embodiment of the present invention;

FIG. 6 illustrates a top plan view of the exemplary modular device base of FIG. 5;

FIG. 7 illustrates a perspective view of another exemplary modular device of the present invention, comprising a base, intermediate module, and flat surface attachment module having a candle positioned thereon; and

FIG. 8 illustrates another perspective view of the exemplary modular device of FIG. 7 having a kettle positioned thereon.

### DETAILED DESCRIPTION OF EXEMPLARY EMBODIMENT(S)

Various embodiments of the present invention will now be described in detail with reference to the accompanying drawings. In the following description, specific details such as detailed configuration and components are merely provided to assist the overall understanding of these embodiments of the present invention. Therefore, it should be apparent to those skilled in the art that various changes and modifications of the embodiments described herein can be made without departing from the scope and spirit of the present invention. In addition, descriptions of well-known functions and constructions are omitted for clarity and conciseness.

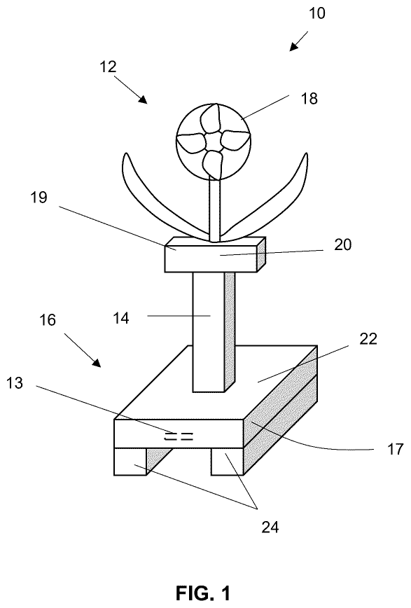

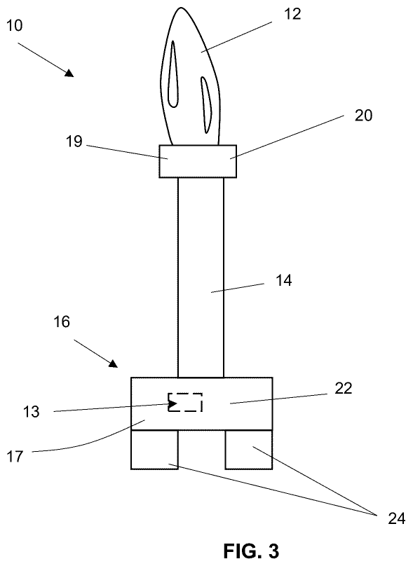

Referring now to FIGS. 1-3, various views of an exemplary modular device 10 comprising a pedestal base 16 (having housing 17) and shaft 14, and fan attachment 12 are shown. The device 10 may be customizable to support any number of different attachments, and to provide for any number of different configurations. The base 16 may comprise a power module 13 in electronic communication with a port 34. The power module 13 may permit the base 16 to transmit electric power to any number of different electronic components connected to one or more ports (e.g., 34) of the base 16. The power module may comprise one or more batteries (e.g., rechargeable batteries), power boards, transformers, circuits, charging ports (e.g., USB units), plugs, AC power sources, DC power sources, some combination thereof, or the like. The base 16 may include a main portion 22 having a substantially flat top surface and support legs 24. The power module may be positioned in the main portion 22 of the base 16.

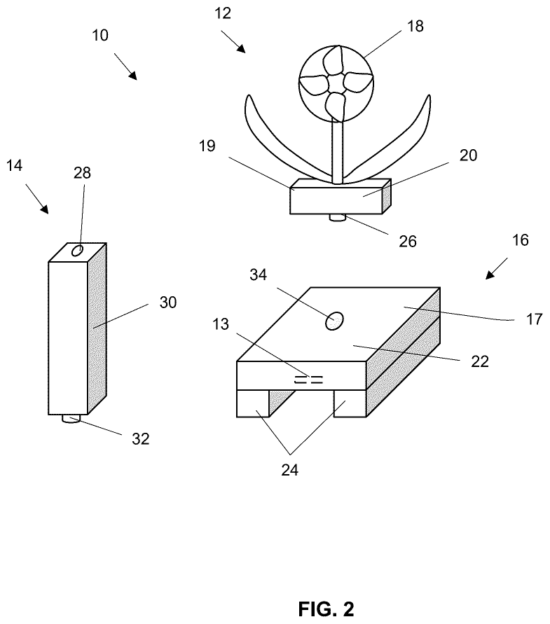

The main portion 22 of the base 16 may comprise a port 34 configured to receive a connector (e.g., 32, 26). Referring specifically to FIG. 2, a connector 32 of an intermediate portion pedestal shaft 14 may be positioned in the port 34 of the base 16 to establish electronic communication between the base 16 and the pedestal shaft 14. Alternatively, or additionally, a connector 26 of a fan attachment 12 may be positioned in the port 34 of the base 16 to establish electronic communication between the base 16 and the fan attachment 12. Referring again to FIGS. 1-3, when the connector 32 of the pedestal shaft 14 is positioned in the port 34 of the base 16, the connector 26 of the fan attachment 12 may be positioned in a port 28 of the pedestal shaft 14 to permit the pedestal shaft 14 to transmit power from the base 16 to the fan attachment 12. Power may be transmitted at each connection between a port 34, 28 and connector 32, 26. One or more circuits (e.g., including one or more wires) may transmit power from the connector 32 of the pedestal shaft 14 to the port 28 of the pedestal shaft 14. The transmission of power from the connector 32 to the port 28 in the pedestal shaft 14 may occur by way of known methods.

The pedestal shaft 14 may have a body/housing 30 that is substantially rectangular prism-shaped, although such is not required. It is also not required that an intermediate member between an exemplary base and an exemplary attachment be a pedestal shaft. Any number of different intermediate members of any number of different shapes, sizes/dimensions, materials, designs and the like may be employed without departing from the scope of the present invention. Likewise, the base is not limited to any particular number, shape, size/dimensions, material composition, design and the like. In this particular embodiment, the attachment is a fan attachment 12 comprising a decorative fan 18 (substantially resembling a flowering plant), a lower portion 20, and a connector 26. The attachment may include a housing 19. The connector 26 may transmit power from the base 16 and/or the pedestal shaft 14 to the fan 18. The lower portion 20 may provide base structural support to the fan 18.

The present invention is not limited to any particular electronic device for the attachment. An exemplary attachment may comprise any number of different electronic and/or non-electronic components of various sizes/dimensions, shapes, designs (e.g., colors), material compositions, power requirements/electronic configurations, and the like without departing from the scope of the present invention. By way of example and not limitation, the components of an attachment may comprise one or more fans (e.g., misting fans), lanterns, other lights and/or light emitting devices (e.g., light up signs, painting lamps, bug zapping lamps, stylish, multidirectional lighting, such as for photograph opportunities, and the like) sound emitting devices, fragrance emitting devices (e.g., sent diffusers), heat emitting devices (e.g., warming plates, electric heaters such as for use on a patio), other electronic devices, flat surfaces (e.g., table tops, podium tops), signs, non-electronic devices, some combination thereof, and/or any other device configured with an exemplary connector capable of receiving or being received by a base and/or intermediate module.

Connection between the base 16 and the pedestal shaft 14 may be immediate when the connector 32 of the pedestal shaft 14 is positioned in the port 34 of the base 16. The pedestal shaft 14 and base 16 may readily be disconnected thereafter by, e.g., twisting, pulling, some combination thereof, or the like the base 16 and pedestal shaft 14 with respect to one another. The connector 32 may be a retractable part integrated to the bottom of the pedestal shaft 14. The port 34 may be configured to be covered by a cap (not shown) when the base 16 is not in use. The cap may protect electronic components of the base 16 from dust and/or moisture when the base 16 is not in use.

Likewise, connection between the base 16 and attachment 12 may be immediate when the connector 26 of the attachment 12 is positioned in the port 34 of the base 16. The attachment 12 and base 16 may readily be disconnected thereafter by, e.g., twisting, pulling, some combination thereof, or the like the base 16 and attachment 12 with respect to one another. When the pedestal shaft 14 is attached to the base 16, connection between the attachment 12 and the pedestal shaft 14 may be immediate when the connector 26 of the attachment 12 is positioned in the port 28 of the pedestal shaft 14. The attachment 12 and pedestal shaft 14 may readily be disconnected thereafter by, e.g., twisting, pulling, some combination thereof, or the like the pedestal shaft 14 and attachment 12 with respect to one another.

The port 28 of the pedestal shaft 14 may be configured to be covered by a cap (not shown) when the pedestal shaft 14 is not in use. The cap may protect electronic components of the pedestal shaft 14 from dust and/or moisture when the pedestal shaft 14 is not in use. An exemplary port cap for the base 16 and/or the pedestal shaft 14 may be stored within the base when not in use, although such is not required. The cap may be configured to be positioned flush with the top surface of the base 16 (e.g., to permit objects such as other devices 10 to be stacked on the base 16 when the device 10 is not in use) (multiple bases may be stacked on one another for storage). The connector 26 of the attachment 12 may be a retractable part integrated to the bottom portion 20 of the attachment 12. The connectors 26, 32 may be retractable and/or removable prongs. For example, removal of the connector 26 from the attachment 12 may permit the attachment 12 to be rested on a flat surface.

An exemplary attachment (e.g., 12) may include one or more batteries, preferably rechargeable batteries, configured to allow the electronic device(s) of the attachment to be used when the attachment is a standalone device. For example, the fan attachment 12 of FIGS. 1-3 may be charged by the base 16, and then may be used as a standalone device (e.g., at a pool, patio, backyard). The fan attachment 12 may be returned to the remainder of the device 10 after standalone use for charging. The base 16 may be configured to power/charge any number of different devices (not just the fan attachment 12). As a specific, non-limiting example, after a fan attachment 12 is removed from the base 16 (e.g., which may be located in a bedroom), an attachment including a light fixture may be charged using the base 16. The attachment 12 may also be powered/charged by any number of different bases (not just the base 16 of FIGS. 1-3). As a specific, non-limiting example, a first exemplary base may be positioned inside in a bedroom, and a second exemplary base may be positioned outside on a patio. The user may link the attachment 12 to each the first and second bases depending on where the user is going to be located.

The fan attachment 12 may also be propped up on the base 16 or pedestal shaft 14, which may be used to regulate air flow (e.g., at a particular height). The length of the pedestal shaft 14 may be adjusted between any number of different lengths in certain embodiments. The fan attachment 12 may be configured with any number of different joints, hinges, some combination thereof, or the like for permitting the angle of the fan to be adjusted. The base 16 and/or the pedestal shaft 14 may be configured with any number of different ports (e.g., 34, 28), such as, for example, AC outlets/ports, USB ports, some combination thereof, or the like. Each portion 12, 14, 16 of the device is preferably made in accordance with outdoor rating guidelines, such that the device 10 may be used both indoors and outdoors.

Power distribution mechanisms between the various portions 12, 14, 16 of the device 10 may comprise any number of different connector types and known power transmission mechanisms. Device batteries may involve any number of different charging requirements, and may comprise any number of different materials and/or components. Although not required, device batteries may be recharged by a wind turbine attachment, solar panel, some combination thereof, or the like.

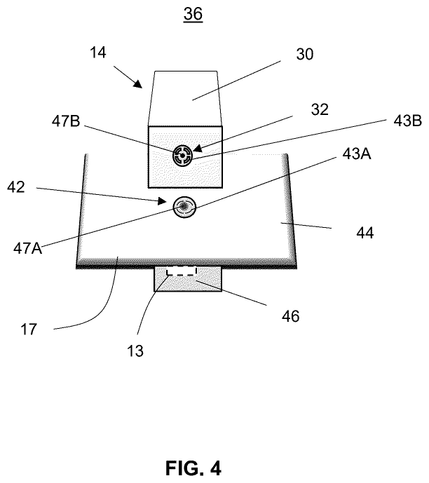

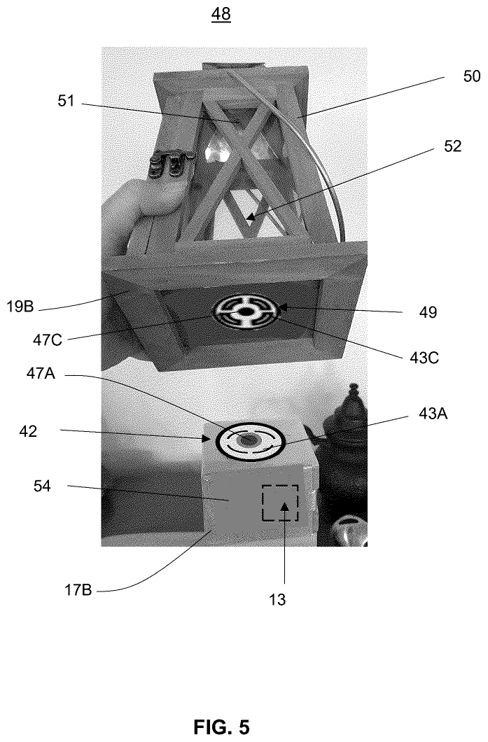

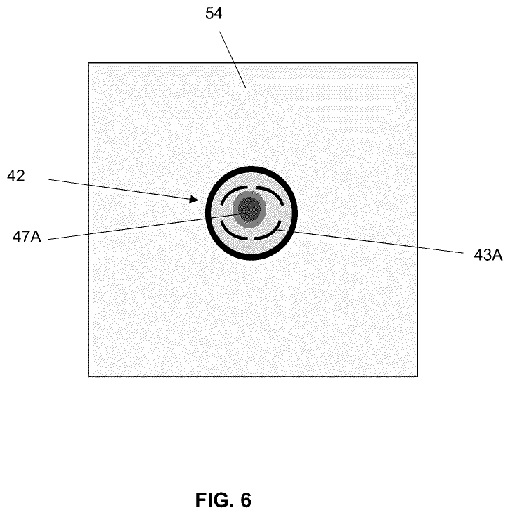

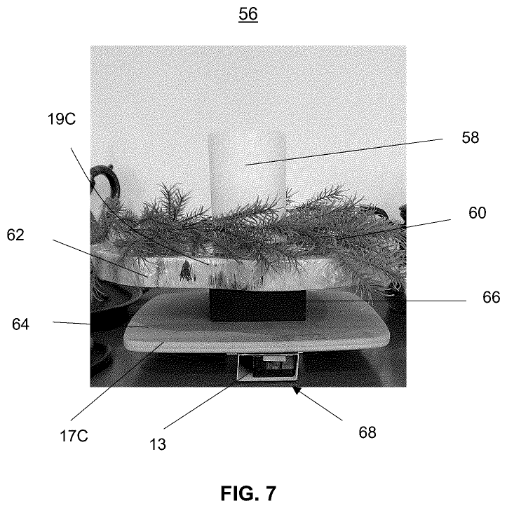

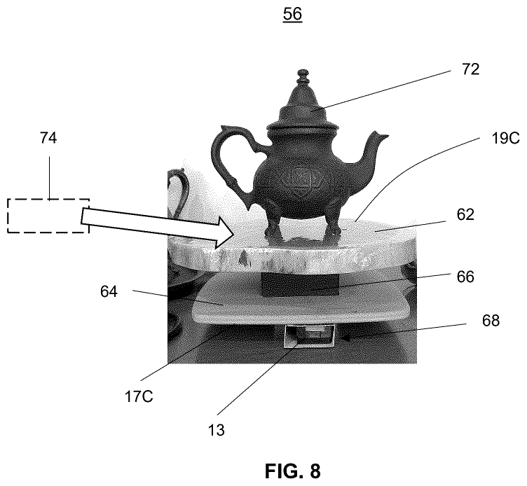

Referring now to FIG. 4, a device 36 is shown where an intermediate attachment 14 (e.g., pedestal shaft having housing/body 30) having a connector 32 (including an electrical terminal 47B and mechanical coupling 43B—e.g., ridges, other protrusions, depressions, receptacles, some combination thereof, or the like) is prepared for attachment to an exemplary base 44 having a base support unit 46 and port 42 (having an electrical terminal 47A and mechanical coupling 43A—e.g., ridges, other protrusions, depressions, receptacles, some combination thereof, or the like). In this particular embodiment, male members of the connector 32 are configured to be received by female members of the port 42. The male versus female members may be exchanged for one another. A twisting motion of the connector 32 may secure the connector 32 to the port 42 (e.g., the twisting motion may rotate swiveling pins of the connector 32 into a secure position within the female members of the port 42). The base 44 in FIG. 44 may be exchanged with the base 16 in FIGS. 1-3, the base 54 in FIGS. 5-6, and/or the base 64 in FIGS. 7-8. The particular design, shape, size/dimensions, material composition, some combination thereof, or the like of the ports and connectors may be varied without departing from the scope of the present invention.

Still referring to FIG. 4, the port 42 may be configured to rotate to cause spinning motion of the pedestal shaft 14, although such is not required. Electricity may be transmitted from a power module 13 of the base 44 to the pedestal shaft 14 by way of the port 42 and attached connector 32. The base 44 may also be configured to charge more than one device at once (e.g., by way of multiple ports 42). Exterior surfaces of the device 36 may include waterproof material, such as, for example, high-density polyethylene (HDPE), which may protect electronic components inside the device 36 from moisture. It is not required, however, that each component (e.g., 14, 44) of the device comprise the same exterior surface material. Each connection between a connector and port is also preferably rated as waterproof, in accordance with outdoor use. Certain device components may include a telescoping shaft for adjusting the length thereof.

Referring to FIGS. 5-6, a device 48 is shown involving a lantern attachment 50 (having housing 19B) configured to be attached to a base 54 (having housing 17B and power module 13). A connector 49 (having an electrical terminal 47C and mechanical coupling 43C—e.g., ridges, other protrusions, depressions, receptacles, some combination thereof, or the like) may be positioned at the bottom of the lantern attachment 50, and may permit the lantern attachment 50 to be in electronic communication with the base 54. For example, the connector 49 may be inserted into a port 42 (having an electrical terminal 47A and mechanical coupling 43A—e.g., ridges, other protrusions, depressions, receptacles, some combination thereof, or the like) of the base 54 to secure the lantern attachment 50 to the base, and to establish electronic communication between the base 54 and the lantern 50. One or more lights 51 may be positioned in an interior portion 52 of the lantern. An intermediate module (e.g., module 14 from FIG. 2, not shown in FIGS. 5-6) may be positioned between the base 54 and lantern attachment 50, and may transmit power from the base 54 to the lantern attachment 50.

The base 54 may include a power module 13 involving, e.g., an AC receptacle/power supply input, AC distribution, a power switch, DC charging and output/distribution, one or more circuits, one or more batteries (rechargeable and/or non-rechargeable), USB modules, outlet units, some combination thereof, or the like. A detachable cord may be configured to transmit power to the AC receptacle. The cord may be linked to prongs that connect with outlets from a wall or extension cord to obtain AC power and pass said power through a conductive wire to the base 54. The AC receptacle may include a cover to protect the receptacle (e.g., from dust and moisture) when it is not in use. The power module 13 of the base 54 may be configured to transmit power to any attachments and/or intermediate modules linked to the base 54 (e.g., by way of ports, connectors, USB modules, one or more circuits, transformers, adaptors, inverters, some combination thereof, or the like). The power module 13 may include a rechargeable battery (e.g., secured within a slot/compartment in the base 54, or positioned proximate to the base). The rechargeable battery may be an EGO battery, although such is not required. An intermediate module (e.g., a pedestal shaft) may also include a rechargeable battery (e.g., secured within a slot/compartment in the pedestal shaft). A battery compartment may include a press to release a battery from the compartment when it is desired to exchange the battery. The battery release and other device components are each preferably weather resistant.

Referring now to FIGS. 1-2 and 5, a user may connect any number of different attachments to an exemplary base and/or intermediate module to achieve a desired function. As a non-limiting example, where a user no longer wishes to use the fan attachment 12 with device 10 and instead wishes to use a lamp in association with the base 16 of device 10 (e.g., on a patio after sunset when the temperature is lower and it is darker outside), the user may remove the fan attachment 12 (and optionally the pedestal shaft 14) from the base 16, and thereafter position the connector 49 of a lantern attachment 50 in the port 28 of the pedestal shaft 14 (which may resemble port 42), or optionally the port 34 of the base 16 (which may resemble port 42) to use the lantern attachment 50 in association with the base 16. The power module 13 of the base 16 (and/or a power module of the pedestal shaft 14) may transmit power through the connector 49 to one or more lights 51 of the lantern attachment 50. Transmission of power between a port and connector may occur by way of known power transmission methods. The lantern attachment 50 may comprise a bug/mosquito zapping lamp (thus, an exemplary device may be particularly advantageous for camping). Any attachment (e.g., 12, 50) may be modular and interchangeable.

As another non-limiting example, an attachment having an integrated sound emitting device (e.g., for playing music) may include a connector (e.g., 49), and may be connected to the base 54 of device 48, the base 16 of device 10, a similar base (e.g., 44 in FIG. 4), or an intermediate module (e.g., 14) connected to a base (e.g., 16, 54). As yet another non-limiting example, an attachment having a fragrance emitting device (e.g., a scent diffuser) may be connected to the base 54 of device 48, the base 16 of device 10, a similar base (e.g., 44 in FIG. 4), or an intermediate module (e.g., 14) connected to a base (e.g., 16, 54). As yet another non-limiting example, an attachment having a heat emitting device (e.g., a heat lantern for keeping the user warm at night) may be connected to the base 54 of device 48, the base 16 of device 10, a similar base (e.g., 44 in FIG. 4), or an intermediate module (e.g., 14) connected to a base (e.g., 16, 54). Different attachments may be exchanged with one another and connected to an exemplary base (e.g., 16, 54) and/or intermediate module (e.g., pedestal shaft 14) based on the user's preference for the device to provide any number of different particular functions (e.g., providing cooling, providing lighting, providing sound, providing fragrance, providing heating, some combination thereof, or the like).

Referring to FIG. 7, an exemplary modular device 56 comprising a base 64 (having housing 17C and power module 13), intermediate module 66, and flat surface attachment module 62 (having housing 19C) is shown, where a candle 58 (e.g., electric light candle) and decorative garland 60 are positioned on the attachment module 62. The intermediate module 66 may be secured by way of a connector to the base 64, and the attachment module 62 may be secured by way of a connector to the intermediate module 66. Here, it is not required that the intermediate module 66 transmits power from the base 64 to the attachment module 62. Although not shown, one or more charging ports (e.g., USB ports) may be provided at one or more device components. Non-skid/slip padding may be provided at the bottom portion 68 of the base to prevent the device 56 from sliding on or scratching a support surface. The device 56 may include one or more storage compartments (e.g., including a storage compartment at the bottom portion 68 of the base 64).

Referring to FIG. 8, the exemplary modular device 56 comprising a base 64 (having housing 17C and bottom portion 68 with power module 13), intermediate module 66, and flat surface attachment module 62 of FIG. 7 (having housing 19C) is shown, where a kettle 72 is positioned on the attachment module 62. It will be apparent to one of ordinary skill in the art that any number of different objects and/or materials may be positioned an exemplary flat surface attachment module without departing from the scope of the present invention. A port (not shown) of the base 64 may be configured to rotate the intermediate module 66 and attachment module 62, although such is not required. Alternatively, or additionally, a hot plate 74 may be positioned at the attachment module 62 (e.g., for heating the kettle 72). Power may be transmitted from the base 64 through the intermediate module 66 to the hot plate 74.

Any embodiment of the present invention may include any of the features of the other embodiments of the present invention. The exemplary embodiments herein disclosed are not intended to be exhaustive or to unnecessarily limit the scope of the invention. The exemplary embodiments were chosen and described in order to explain the principles of the present invention so that others skilled in the art may practice the invention. Having shown and described exemplary embodiments of the present invention, those skilled in the art will realize that many variations and modifications may be made to the described invention. Many of those variations and modifications will provide the same result and fall within the spirit of the claimed invention. It is the intention, therefore, to limit the invention only as indicated by the scope of the claims.

Certain operations described herein may be performed by one or more electronic devices. Each electronic device may comprise one or more processors, electronic storage devices, executable software instructions, and the like configured to perform the operations described herein. The electronic devices may be general purpose computers or specialized computing devices. The electronic devices may comprise personal computers, smartphone, tablets, databases, servers, or the like. The electronic connections and transmissions described herein may be accomplished by wired or wireless means. The computerized hardware, software, components, systems, steps, methods, and/or processes described herein may serve to improve the speed of the computerized hardware, software, systems, steps, methods, and/or processes described herein.

What is claimed is:

1. A modular device with interchangeable parts, comprising:
a base, comprising a base housing, power module and a first port, wherein the first port is in electronic communication with the power module;
an attachment, comprising an attachment housing and a first connector;
wherein the first port is configured to transmit power through the first connector into the attachment; and
wherein the first connector is configured for mechanical connection to the first port to cause the attachment to be removably secured above the base.

2. The device of claim 1, wherein the power module comprises one or more batteries.

3. The device of claim 1, further comprising an intermediate attachment having an intermediate attachment housing, a second connector and a second port, wherein the second connector is configured for mechanical connection to the first port to removably secure the intermediate attachment to the base, wherein the first connector is configured for mechanical connection to the second port to removably secure the attachment to the intermediate attachment, and to establish an electrical path from the power module through the intermediate attachment to the attachment.

4. The device of claim 1, wherein the attachment comprises an electronic device capable of being powered by the power module of the base.

5. The device of claim 3, wherein the attachment comprises an electronic device capable of being powered by the power module of the base, and the intermediate attachment is configured to transmit power from the power module to the electronic device.

6. The device of claim 3, wherein the intermediate attachment housing defines an elongated pedestal shaft.

7. A modular electronic device with interchangeable parts, the device comprising:
a base, including a first housing, a power module disposed within the first housing, and a first interface comprising a port having a first mechanical coupling and a first electrical terminal, wherein the first interface is located at a top face of the base;
a first attachment, including a second housing, a second interface comprising a second mechanical coupling and a second electrical terminal, wherein the second interface is configured, when engaged with the first interface, to mechanically secure the first attachment to the base, and to establish an electrical path from the power module to the first attachment; and
wherein the first attachment is configured to be secured above the base.

8. The device of claim 7, further comprising a second attachment configured to be removably secured between the base and first attachment, and to establish an electric path from the first interface to the second interface.

9. The device of claim 8, wherein the second attachment is configured to be removably secured above the base and below the first attachment.

10. The device of claim 7, wherein the first attachment further comprises an electronic device configured to receive power from the second interface.

11. The device of claim 10, wherein the electronic device includes a fan.

12. The device of claim 10, wherein the electronic device includes a light.

13. The device of claim 10, wherein the electronic device includes a hot plate.

14. A modular electronic device with interchangeable parts, the device comprising:
a base, including a first housing, a power module disposed within the first housing, and a first interface comprising a port having a first mechanical coupling and a first electrical terminal, wherein the first interface is located at a top face of the base;
a first attachment, including a second housing, a second interface comprising a second mechanical coupling and a second electrical terminal, and a third interface comprising a third mechanical coupling and a third electrical terminal, wherein the second interface is configured, when engaged with the first interface, to mechanically secure the first attachment to the base, and establish an electrical path from the power module to the third electrical terminal; and
a second attachment, including a third housing, a fourth interface comprising a fourth mechanical coupling and a fourth electrical terminal, wherein the fourth interface is configured, when engaged with the third interface, to mechanically secure the second attachment to the first attachment, and establish an electrical path from the first attachment to the second attachment.

15. The device of claim 14, wherein the second interface is located at a bottom surface of the first attachment.

16. The device of claim 15, wherein the third interface is located at a top surface of the first attachment.

17. The device of claim 16, wherein the fourth interface is located at a bottom surface of the second attachment, and the first attachment is configured to be removably secured above the base and below the second attachment.

18. The device of claim 14, wherein the second attachment includes an electronic device configured to receive power from the fourth interface.

19. The device of claim 18, wherein the electronic device of the second attachment is a fan.

20. The device of claim 18, wherein the electronic device of the second attachment is a light.
